(19) United States
(12) Patent Application Publication
(10) Pub. No.: US 2007/0205809 A1
(43) Pub. Date: Sep. 6, 2007

(54) Semiconductor device, and power supply device and image pickup device using the same

(75) Inventor: Kenya Kondo, Ukyo-ku, Kyoto (JP)

Correspondence Address: ROHM CO., LTD.;C/O KEATING & BENNETT, LLP, 8180 GREENSBORO DRIVE, SUITE 850, MCLEAN, VA, 22102, US

(73) Assignee: ROHM CO., LTD., Ukyo-ku, Kyoto (JP)

(21) Appl. No.: 11/549,180

(22) Filed: Oct. 13, 2006

(30) Foreign Application Priority Data
Oct. 14, 2005 (JP) 2005-300243
Jun. 27, 2006 (JP) 2006-176071

(51) Int. Cl. H03K 5/22

(52) U.S. Cl. 327/63

(57) ABSTRACT

An electronic circuit includes a semiconductor device which has an internal circuit that uses a positive power supply voltage and a negative power supply voltage, and which controls the operation of the above-mentioned internal circuit by an external input. The semiconductor device includes an input signal detection circuit that operates using a voltage that is input into the external input, and a signal output circuit which outputs a signal that controls the negative power supply voltage applied to the internal circuit in accordance with an output of the input signal detection circuit. The circuit can switch a negative-side circuit on and off without depending on a positive power supply voltage and also without depending on the order of starting a positive power supply voltage and a negative power supply voltage.

### BACKGROUND OF THE INVENTION

1. Field of the Invention

The present invention relates to a semiconductor device that has positive and negative power supply voltages and that does not depend on the order of the application of the power supplies.

2. Description of the Related Art

In electrical devices using a plurality of voltages, there are cases in which the internal circuit must be controlled using a voltage that is lower than an ordinary reference voltage (e.g., 0 V). In the circuit shown in FIG. 7 in which the content of Japanese Patent Application Kokai No. S63-75810 is partially modified as one such example, the on/off control of a circuit 230 (hereinafter referred to as “negative-side circuit”) that uses a reference voltage GND and a voltage Vee (hereinafter referred to as “negative power supply voltage”) that is lower than this reference voltage as the operating voltage is performed by using a voltage Vcc (hereinafter referred to as “positive power supply voltage”) that is higher than the reference voltage GND.

However, in the circuit shown in FIG. 7 that uses a negative power supply, a switching signal is first input into the negative-side circuit 230 using a positive power supply voltage Vcc at the time of the on/off control of the negative output by means of the negative-side circuit 230. Therefore, even if the negative-side circuit 230 is a circuit that uses only the reference voltage GND and negative power supply voltage Vee, the positive power supply voltage Vcc is required.

Furthermore, in a circuit in which the switching of a negative-side circuit 231 is controlled using an external input (SW) as shown in FIG. 8, even if the negative-side circuit 231 is a circuit that uses only the reference voltage GND and negative power supply voltage Vee, there is a restriction on the order of the application of the power supply voltages in that a switch input cannot be accepted unless the positive power supply voltage Vcc and negative power supply voltage Vee are first switched on.

A signal generation circuit that generates a start signal for a negative voltage output regulator (negative constant voltage source) including a switching function (output on/off function) may be used as an example of the above-mentioned negative-side circuits 230 and 231.

The negative voltage output regulator including a switching function initiates the output operation of a negative voltage when the logic of the above-mentioned start signal is enabled. Immediately following this start, however, an excessive incoming current flows at one time to an uncharged smoothing capacitor that is connected to the output terminal, so that there is a concern of causing abnormal heat generation or damage to the circuit elements (see FIG. 10A).

Therefore, conventional negative voltage output regulators are equipped with a soft-start function to minimize the above-mentioned incoming current. Furthermore, in conventional negative voltage output regulators, an arrangement in which an externally attached capacitor Ca is charged using a constant current source Ia installed inside the integrated circuit (see FIG. 11A), or an arrangement in which a capacitor Cb installed inside the integrated circuit is similarly charged using a constant current source Ib installed inside the integrated circuit (see FIG. 11B) is generally used to generate a soft-start signal required for achieving the above-mentioned soft-start function (i.e., a voltage signal that initiates the gradual transition of the voltage level using the enabling of the start signal as a trigger).

However, in the arrangement of FIG. 11A, although it is possible to gain a sufficient soft-start time by externally connecting a capacitor Ca having a large capacitance, a dedicated pin Tc for externally connecting one end of the capacitor Ca is required, so that there is a problem in that a reduction in the package size is inhibited. Moreover, in the arrangement of FIG. 11B, although an increase in the number of pins can be avoided, it is necessary to increase the capacitance of the capacitor Cb installed inside the integrated circuit in order to gain a sufficient soft-start time, which leads to the problem of an increase in the chip area. In the arrangement of FIG. 11B, however, while the soft-start time can also be extended by making the current value of the constant current source Ib very small, if the current value of the constant current source Ib is reduced to an extremely small value, the effect of high-temperature leaks or the like is increased, so that it is difficult to achieve the soft-start time.

Furthermore, besides the above-mentioned prior art, Japanese Utility Model Application Kokai No. H06-66292 (Patent Reference 2) and Japanese Patent Application Kokai No. 2004-88964 (Patent Reference 3) can be cited as examples of the prior art relating to the soft-start function of a power supply device. Patent Reference 2 discloses a power supply circuit in which a first resistor and a capacitor that are connected in parallel are connected between a second resistor, one end of which is grounded, and an output terminal. A voltage V1 obtained by dividing an output voltage Vout by the first and second resistors and a voltage V2 that defines a difference from the threshold voltage Vrf1 are output by a subtractor. The driving of a chopper circuit is controlled by a binary voltage V4 obtained by comparing the voltage V2 and a triangular wave voltage Vtr, the above-mentioned capacitor is charged by a charging circuit immediately following the start, and the soft-start time is set by the discharge of this capacitor. However, the prior art in Patent Reference 2 is a technique used to make the soft-start time constant without depending on the input voltage Vin at all, and is not devised with a reduction in the package size or chip area in mind.

Patent Reference 3 discloses a switching power supply device that returns an output voltage and compares this output voltage with a reference voltage, and performs a pulse width modulation control on the basis of the above-mentioned comparison results, thus stabilizing the above-mentioned output voltage. With this switching power supply device, a soft-start for starting the above-mentioned comparison operation is output by a step waveform voltage. In this prior art, an externally attached capacitor is not required, so that a package size reduction is possible. However, a plurality of capacitors must to be installed inside an IC, and a step waveform voltage generator is also required. Accordingly, the chip area must be reduced even further.

### SUMMARY OF THE INVENTION

In order to overcome the problems described above, preferred embodiments of the present invention switch a negative-side circuit on and off without depending on a positive power supply voltage and also without depending on the order of starting the positive power supply voltage and negative power supply voltage. The power supply voltage refers to a voltage that is used to operate a specified circuit.

Furthermore, preferred embodiments of the present invention effectively minimize the incoming current that is generated at the start of the power supply device while also minimizing an increase in the package size or chip area.

A first preferred embodiment of the present invention includes a semiconductor device having an internal circuit that uses a positive power supply voltage and a negative power supply voltage, and the operation of the internal circuit is controlled by an external input. The semiconductor device preferably includes an input signal detection circuit which operates using a voltage that is input as the external input, and a signal output circuit which outputs a signal that controls the negative power supply voltage applied to the internal circuit in accordance with the output of the input signal detection circuit.

A second preferred embodiment of the present invention includes a semiconductor device preferably including a first terminal to which a first voltage is applied; a second terminal to which a second voltage that is higher than the first voltage is applied; a third terminal to which a third voltage that is between the first voltage and second voltage is applied; a fourth terminal to which a fourth voltage that is lower than the first voltage is applied; a detection circuit into which an input signal from the third terminal and a specified first reference voltage between the first voltage and second voltage are input, and which outputs a first output signal in accordance with the difference between the input signal and the first reference voltage; an auxiliary circuit into which the first output signal of the detection circuit and a specified second reference voltage between the first voltage and second voltage are input; and a signal output circuit into which a third reference voltage that is a specified voltage between the first voltage and fourth voltage and a second output signal from the auxiliary circuit are input, and which outputs a third output signal in accordance with the second output signal, wherein the third output signal is output in accordance with the signal that is input into the third terminal.

The first and second preferred embodiments of the present invention may also include the semiconductor device having the detection circuit described above, wherein the first reference voltage is output from the connection point between a first resistor, one end of which is connected to the first terminal, and a second resistor, one end of which is connected to the third terminal and the other end of which is connected to the other end of the first resistor.

The first and second preferred embodiments of the present invention may also include the semiconductor device described above, wherein the semiconductor device has the detection circuit having a first transistor whose base terminal is connected to the connection point between the first resistor and second resistor, and whose emitter terminal is connected to the first terminal, and outputting the first output signal in accordance with the output signal from the collector terminal of the first transistor.

The first and second preferred embodiments of the present invention may also include the semiconductor device having the auxiliary circuit described above, wherein the second reference voltage is output from the connection point between a third resistor, one end of which is connected to the output of the detection circuit, and a fourth resistor, one end of which is connected to the other end of the third resistor and the other end of which is connected to the third terminal.

Furthermore, the first and second preferred embodiments of the present invention may also include the semiconductor device described above, wherein the semiconductor device has the auxiliary circuit having a second transistor whose base terminal is connected to the connection point between the third resistor and the fourth resistor, and whose emitter terminal is connected to the third terminal, and outputting the second output signal in accordance with the voltage generated at the fourth resistor that is connected between the collector terminal of the second transistor and the third terminal.

A third preferred embodiment of the present invention includes a semiconductor device preferably including a first terminal to which a first voltage is applied; a second terminal to which a second voltage that is higher than the first voltage is applied; a third terminal to which a third voltage that is between the first voltage and second voltage is applied; a fourth terminal to which a fourth voltage that is lower than the first voltage is applied; a detection circuit into which an input signal from the third terminal and a specified first reference voltage between the first voltage and second voltage are input, and which outputs a first output signal in accordance with the difference between the input signal and the first reference voltage; an auxiliary circuit which outputs a second output signal in accordance with the signal that is input into the third terminal by an input-side transistor of a current mirror whose emitter is connected to the third terminal, and into which the first output signal is input, and an output-side transistor of the current mirror; and a signal output circuit into which a third reference voltage that is a specified voltage between the first voltage and fourth voltage and the second output signal from the auxiliary circuit are input, and which outputs a third output signal in accordance with the second output signal, wherein the third output signal is output in accordance with the signal that is input into the third terminal.

A fourth preferred embodiment of the present invention includes a semiconductor device preferably including a first terminal to which a first voltage is applied; a second terminal to which a second voltage that is higher than the first voltage is applied; a third terminal to which a third voltage that is between the first voltage and second voltage is applied; a fourth terminal to which a fourth voltage that is lower than the first voltage is applied; an auxiliary circuit having a level shift circuit which is connected to the third terminal, and into which a first output signal is input; and a signal output circuit into which a third reference voltage that is a specified voltage between the first voltage and fourth voltage and a second output signal from the auxiliary circuit are input, and which outputs a third output signal in accordance with the second output signal, wherein the third output signal is output in accordance with the signal that is input into the third terminal.

The first through fourth preferred embodiments of the present invention may also include the semiconductor device described above, wherein the semiconductor device has a signal output circuit including the first terminal, an input portion into which the second output signal from the auxiliary circuit is input, and a clamp circuit which prevents the application of a voltage that is equal to or higher than a specified fifth voltage to the input portion.

The first through fourth preferred embodiments of the present invention may also be used in an image pickup device including a CCD image sensor that uses the first voltage, second voltage, and third voltage as the operating voltage.

The semiconductor device of another preferred embodiment of the present invention may include a positive power supply terminal that receives the supply of a positive power supply voltage; a negative power supply terminal that receives the supply of a negative power supply voltage; a ground terminal that receives the supply of a ground voltage; an external signal terminal that receives an external signal input that can gain a positive voltage level; a negative voltage output regulator that uses the negative power supply voltage and the ground voltage as the operating voltage and that initiates the output operation of a negative voltage in accordance with a specified start signal; a detection circuit that uses the external signal and the ground voltage as the operating voltage and that generates a specified output signal when the voltage level of the external signal reaches a specified value; and a signal output circuit that uses the negative power supply voltage and the ground voltage as the operating voltage and that generates the start signal in accordance with the output signal.

The semiconductor device of the above-mentioned preferred embodiment may also have an arrangement which includes an output terminal that outputs an output voltage of the negative voltage output regulator, and a feedback terminal that receives an feedback voltage input corresponding to the output voltage, and in which the negative voltage output regulator includes a power transistor that is connected between the output terminal and the negative power supply terminal, and a driver to control the opening and closing of the power transistor so that the feedback voltage and a specified reference voltage coincide.

A power supply device according to another preferred embodiment of the present invention preferably includes the semiconductor device described above and further including an output smoothing capacitor which is externally connected between the output terminal and the ground terminal; and first and second external resistors which are externally connected in series between the output terminal and the ground terminal, and whose connection node is externally connected to the feedback terminal.

The power supply device described above may include a speed-up capacitor that is externally connected between the output terminal and the feedback terminal.

In the power supply device described above, the above-mentioned negative voltage output regulator may include a soft-start circuit which generates a voltage signal that initiates a gradual transition of the voltage level using the start signal as a trigger, and which applies a soft-start to the reference voltage or the control signal itself of the power transistor using the voltage signal.

The image pickup device according to a preferred embodiment of the present invention preferably includes the power supply device according to any of the above-described preferred embodiments, and a CCD image sensor, wherein the image pickup device has an arrangement in which the positive power supply voltage or a positive voltage produced from the positive power supply voltage, a negative voltage produced by the negative voltage output regulator, and the ground voltage are used as the operating voltage of the CCD image sensor.

The preferred embodiments of the present invention make it possible to switch the negative-side circuit on and off by using a switch input as a single power supply voltage without depending on a positive power supply voltage as is necessary in the prior art.

Because the positive power supply voltage is not required for the operation of the switch, there is no restriction on the order of the application of the power supplies. Accordingly, there is no program or circuit necessary to set the input order, so that the design of electrical devices using the preferred embodiments of the present invention is facilitated.

In addition, with the power supply device of the preferred embodiments of the present invention, it is possible to effectively minimize the incoming current that is generated at the start of the power supply device while also minimizing an increase in the package size or chip area.

Other features, elements, processes, steps, characteristics and advantages of the present invention will become more apparent from the following detailed description of preferred embodiments of the present invention with reference to the attached drawings.

### BRIEF DESCRIPTION OF THE DRAWINGS

FIG. 1 is a circuit diagram of a semiconductor device according to a first preferred embodiment of the present invention.

FIG. 2 is a circuit diagram of a semiconductor device according to another preferred embodiment of the present invention.

FIG. 3 is a circuit diagram of a semiconductor device according to another preferred embodiment of the present invention.

FIG. 4 is a circuit diagram of a semiconductor device according to another preferred embodiment of the present invention.

FIG. 5 is a model diagram of an electrical device using the semiconductor device according to another preferred embodiment of the present invention.

FIG. 6 is a model diagram of an image pickup device using the electrical device according to another preferred embodiment of the present invention.

FIG. 7 is a circuit diagram of a circuit using a conventional negative power supply.

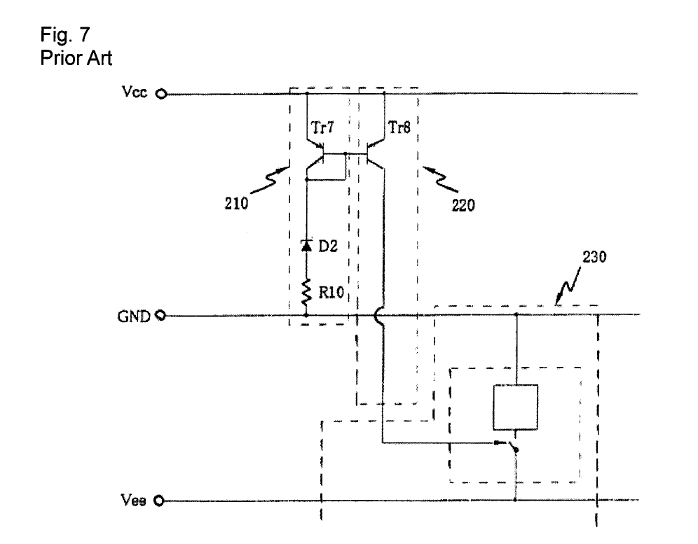

FIG. 8 is a circuit diagram of a circuit using a conventional negative power supply.

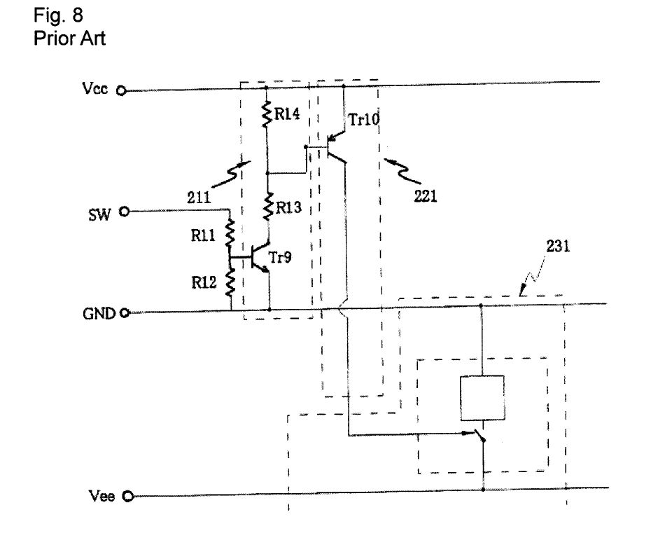

FIG. 9 is a circuit diagram showing a power supply device using the semiconductor device according to another preferred embodiment of the present invention.

FIGS. 10A to 10C are diagrams for illustrating the effect of the soft-start function according to another preferred embodiment of the present invention.

FIGS. 11A and 11B are circuit diagrams showing conventional examples of a soft-start circuit.

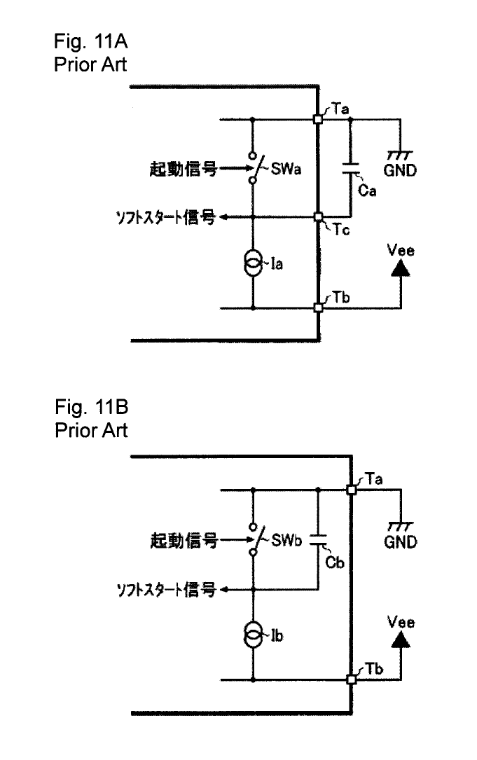

### DETAILED DESCRIPTION OF PREFERRED EMBODIMENTS

The switching of the negative-side circuit on and off without depending on a positive power supply voltage is preferably achieved by using a switch input as a power supply voltage and switching the negative-side circuit on and off.

### First Preferred Embodiment

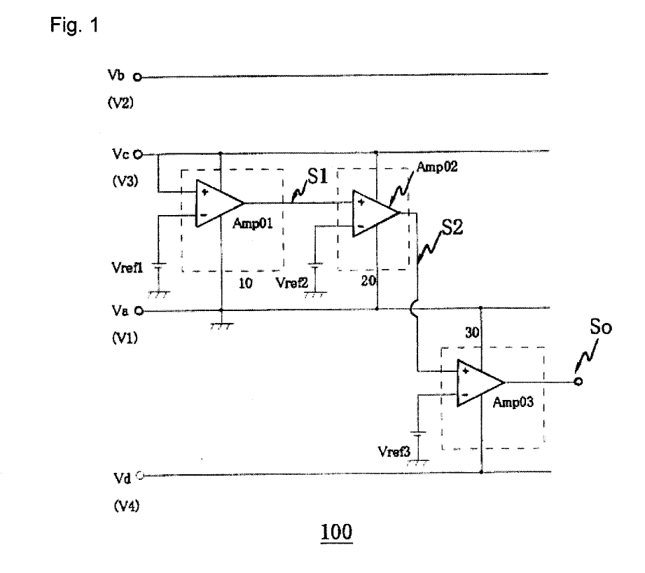

FIG. 1 is a diagram showing a first preferred embodiment of a semiconductor device 100 of the present invention. The semiconductor device 100 includes a detection circuit 10, an auxiliary circuit 20, and a signal output circuit 30. A first voltage V1 (e.g., 0 V) is applied to a first terminal Va. A second voltage V2 (e.g., 5 V) is applied to a second terminal Vb. A third voltage V3 which is equal to or higher than the first voltage V1 and which is equal to or lower than the second voltage V2 is applied to a third terminal Vc. A fourth voltage V4 (e.g., −5 V) is applied to a fourth terminal Vd. The relative magnitudes of the respective voltages is such that V2≧V3≧V1>V4.

The detection circuit 10 is defined by, for instance, a comparator or an error amplifier Amp01; the third terminal Vc is connected to the non-inverting input terminal thereof, while a constant voltage source for producing a first reference voltage Vref1 that is a specified voltage between the first voltage V1 and second voltage V2 is connected to the inverting input terminal thereof. The detection circuit 10 does not use the second voltage V2 from the second terminal Vb as the power supply voltage, but uses the first voltage V1 supplied from the first terminal Va and the third voltage V3 supplied from the third terminal Vc as the power supply voltage. Similarly, the constant voltage source that produces the first reference voltage Vref1 also does not use the second voltage V2 as the power supply voltage, but uses the first voltage V1 and third voltage V3 as the power supply voltage. Accordingly, when the third voltage V3 is applied to the third terminal Vc, the detection circuit 10 can operate regardless of the application of the second voltage V2 applied to the second terminal Vb. In addition, when the third voltage V3 that is equal to or higher than the first reference voltage Vref1 is applied to the third terminal Vc as an input signal, the detection circuit 10 shifts (for example) the voltage level of a first output signal S1, which defines an output, from a low level (e.g., first voltage V1) to a high level (e.g., third voltage V3). Furthermore, the first output signal S1 may also be a signal that depends not only on the voltage, but also on the current.

The auxiliary circuit 20 is defined by, for example, a comparator or an error amplifier Amp02; the first output signal S1 of the detection circuit 10 is applied to the non-inverting input terminal thereof, while a constant voltage source for producing a second reference voltage Vref2 that is a specified voltage between the first voltage V1 and third voltage V3 is connected to the inverting input terminal thereof. The auxiliary circuit 20 does not use the second voltage V2 from the second terminal Vb as the power supply voltage, but uses the first voltage V1 supplied from the first terminal Va and the third voltage V3 supplied from the third terminal Vc as the power supply voltage. Similarly, the constant voltage source that produces the second reference voltage Vref2 also does not use the second voltage V2 as the power supply voltage, but uses the first voltage V1 and third voltage V3 as the power supply voltage. Accordingly, when the first output signal S1 is input into the non-inverting input terminal of the auxiliary circuit 20, the auxiliary circuit 20 can operate regardless of the starting of the second voltage V2 applied to the second terminal Vb. When the first output signal S1 that is equal to or higher than the second reference voltage Vref2 is input into the non-inverting input terminal, the auxiliary circuit 20 shifts (for example) the voltage level of a second output signal S2, which defines an output, from a low level (e.g., first voltage V1) to a high level (e.g., third voltage V3). Furthermore, the second output signal S2 may also be a signal that depends not only on the voltage, but also on the current.

The signal output circuit 30 is defined by, for instance, a comparator or an error amplifier Amp03; the second output signal S2 of the auxiliary circuit 20 is applied to the non-inverting input terminal thereof, while a constant voltage source for producing a third reference voltage Vref3 that is a specified voltage between the first voltage V1 and fourth voltage V4 is connected to the inverting input terminal thereof. The signal output circuit 30 uses the first voltage V1 applied from the first terminal Va and the fourth voltage V4 applied from the fourth terminal Vd as the power supply voltage. Thus, the signal output circuit 30 uses power supply voltages that are independent from the second voltage V2. Accordingly, when the second output signal S2 is applied from the auxiliary circuit 20, the signal output circuit 30 can operate regardless of the starting voltage of the second voltage V2 applied to the second terminal Vb. In addition, when the second output signal S2 that is equal to or higher than the third reference voltage Vref3 is input into the non-inverting input terminal as an input signal, the signal output circuit 30 shifts (for example) the voltage level of a third output signal So, which defines an output, from a low level (e.g., fourth voltage V4) to a high level (e.g., first voltage V1). Furthermore, the third output signal So may also be a signal that depends not only on the voltage, but also on the current.

### Second Preferred Embodiment

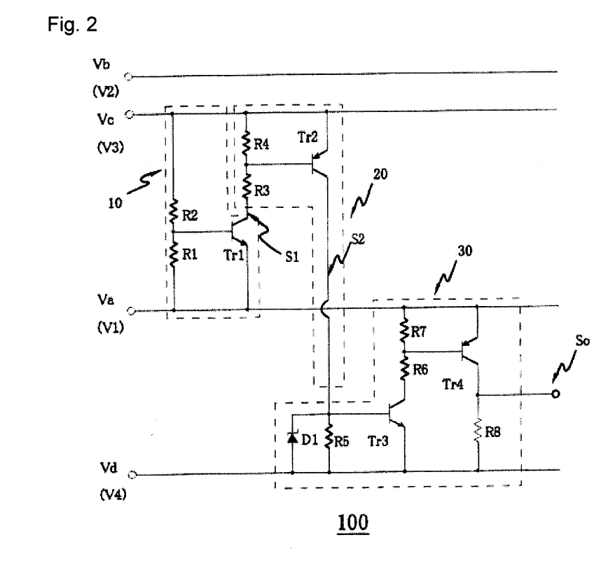

FIG. 2 is diagram showing the arrangement of a second preferred embodiment of the semiconductor device 100 of the present invention. The same numbers are used for the constituent elements that are the same as those shown in FIG. 1, and a detailed description thereof is omitted.

The detection circuit 10 includes a second resistor R2, one end of which is connected to the third terminal Vc, a first resistor R1 one end of which is connected to the first terminal Va, and the other end of which is connected to the other end of the second resistor R2, and an NPN-type first transistor Tr1 to the base terminal of which the connection point of the first resistor R1 and second resistor R2 is connected, and the emitter terminal of which is connected to the first terminal Va. The collector terminal of the first transistor Tr1 outputs the first output signal S1 as the output terminal of the detection circuit 10.

The operation of the detection circuit 10 will be described below. The third voltage V3 that is applied to the third terminal Vc is divided by the first resistor R1 and second resistor R2 and input into the base of the first transistor Tr1. When a voltage that is equal to or higher than a specified voltage (e.g., 0.7 V) is input into the base terminal of the first transistor Tr1 at this point, the first transistor Tr1 becomes electrically continuous. Accordingly, a current flows from the third terminal Vc to the first terminal Va via a third resistor R3, a fourth resistor R4, and the first transistor Tr1, so that the first output signal S1 is output to the auxiliary circuit 20.

The auxiliary circuit 20 includes the third resistor R3, one end of which is connected to the output of the detection circuit 10 (i.e., the collector terminal of the first transistor Tr1), the fourth resistor R4, one end of which is connected to the third terminal Vc, and the other end of which is connected to the other end of the third resistor R3, and a PNP-type second transistor Tr2 to the base terminal of which the connection point of the third resistor R3 and fourth resistor R4 is connected, and the emitter terminal of which is connected to the third terminal Vc. Furthermore, the collector terminal of the second transistor Tr2 outputs the second output signal S2 as the output terminal of the auxiliary circuit 20.

The operation of the auxiliary circuit 20 will be described below. Here, it is assumed that the first transistor Tr1 is electrically continuous as described above. The third voltage V3 that is applied to the third terminal Vc is divided by the third resistor R3 and fourth resistor R4 and input into the base of the second transistor Tr2. When a voltage that is equal to or higher than a specified voltage (e.g., V3−VF: VF is a forward voltage, and is approximately 0.7 V) is input into the base terminal of the second transistor Tr2 at this point, the second transistor Tr2 becomes electrically continuous. A current flows from the third terminal Vc to the fourth terminal Vd, so that the second output signal S2 is output to the signal output circuit 30.

The signal output circuit 30 includes a fifth resistor R5, one end of which is connected to the output of the auxiliary circuit 20 (i.e., the collector terminal of the second transistor Tr2), and the other end of which is connected to the fourth terminal Vd, an NPN-type third transistor Tr3, to the base terminal of which the output terminal of the auxiliary circuit 20 is connected, and the emitter terminal of which is connected to the fourth terminal Vd, a sixth resistor R6, one end of which is connected to the collector terminal of the third transistor Tr3, a seventh resistor R7, one end of which is connected to the first terminal Va, and the other end of which is connected to the other end of the sixth resistor R6, a PNP-type fourth transistor Tr4, the base of which is connected to the connection point of the sixth resistor R6 and seventh resistor R7, and the emitter terminal of which is connected to the first terminal Va, and an eighth resistor R8, one end of which is connected to the fourth terminal Vd, the other end of which is connected to the collector terminal of the fourth transistor Tr4, and which outputs the third output signal So.

The operation of the signal output circuit 30 will be described below. It is assumed that the first transistor Tr1 and second transistor Tr2 are electrically continuous as described above. Because a current also flows to the fifth resistor R5 in this case, voltages appearing at both ends of the fifth resistor R5 are input into the base of the third transistor Tr3. When a voltage that is equal to or higher than a specified voltage (e.g., V4+VF) is input into the base terminal of the third transistor Tr3 at this point, the third transistor Tr3 becomes electrically continuous. Furthermore, as a result of the third transistor Tr3 becoming electrically continuous, voltages are also generated at both ends of the seventh resistor R7. When a voltage that is equal to or lower than a specified voltage (e.g., −0.7 V) is input into the base terminal of the fourth transistor Tr4 at this point, the fourth transistor Tr4 also becomes electrically continuous. Accordingly, the third output signal So is generated at both ends of the eighth resistor R8 in a corresponding manner.

Furthermore, a clamp circuit D1 is provided so that a voltage that is equal to or higher than the specified second voltage V2 is not applied as an input to the signal output circuit. As a result of the clamp circuit D1 being added, for example, even if a voltage that is input into the third terminal Vc reaches a level equal to that of the second voltage V2 as an input to the signal output circuit 30, the clamp circuit D1 can prevent the third transistor Tr3 from operating erroneously. For example, the clamp circuit D1 may use a Zener diode as shown in FIG. 2.

As was described above, in the present preferred embodiment of the present application, by inputting the specified third voltage V3 into the third terminal Vc, a continuous/non-continuous signal can be output to a negative-side circuit (i.e., the signal output circuit 30 in the present preferred embodiment or a subsequent-stage circuit) irrespective of the second voltage V2 applied to the second terminal Vb. For instance, even if the second voltage V2 becomes unstable or a ripple voltage is generated due to the change in the load or the like, there is no possibility of receiving this effect, so that a stable operation can be provided.

### Third Preferred Embodiment

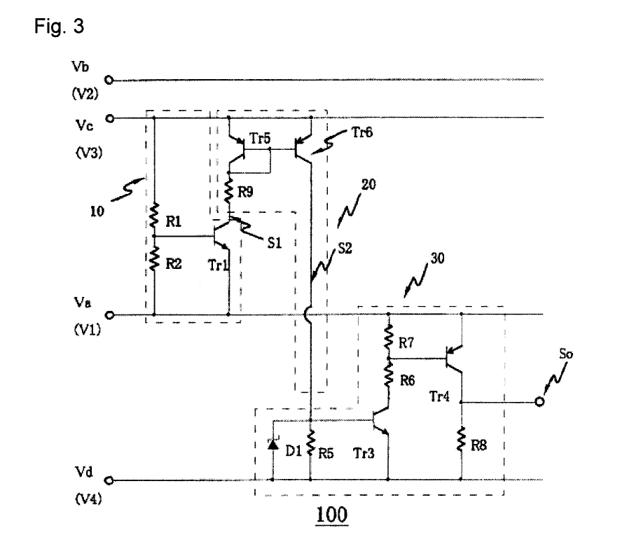

FIG. 3 is a diagram showing another preferred embodiment of the semiconductor device 100 of the present invention. The same numbers are used for constituent elements that are the same as those shown in FIG. 2, and a detailed description thereof is omitted. Because the only element that is different from FIG. 2 is the auxiliary circuit 20, a description of the detection circuit 10 and signal output circuit 30 is omitted.

The auxiliary circuit 20 includes a ninth resistor R9, one end of which is connected to the output of the detection circuit 10 (i.e., the collector terminal of the first transistor Tr1); an input-side transistor Tr5 of a current mirror the emitter terminal of which is connected to the third terminal Vc, and into which the first output signal S1 is input via the ninth resistor R9; and an output-side transistor Tr6 of the current mirror. Furthermore, the collector terminal of the output-side transistor Tr6 of the current mirror outputs the second output signal S2 as the output terminal of the auxiliary circuit 20.

The operation of the auxiliary circuit 20 will be described below. It is assumed that the first transistor Tr1 is electrically continuous as described above. Because of the first transistor Tr1 being electrically continuous, voltages are generated at both ends of the ninth resistor R9. When a voltage that is equal to or higher than a specified voltage (e.g., VC−VF) is input into the base terminal of the input-side transistor Tr5 of the above-mentioned current mirror, the input-side transistor Tr1 of the above-mentioned current mirror becomes electrically continuous. Furthermore, the output-side transistor Tr6 of the above-mentioned current mirror also becomes electrically continuous. Accordingly, the second output signal S2 is output to the signal output circuit 30.

### Fourth Preferred Embodiment

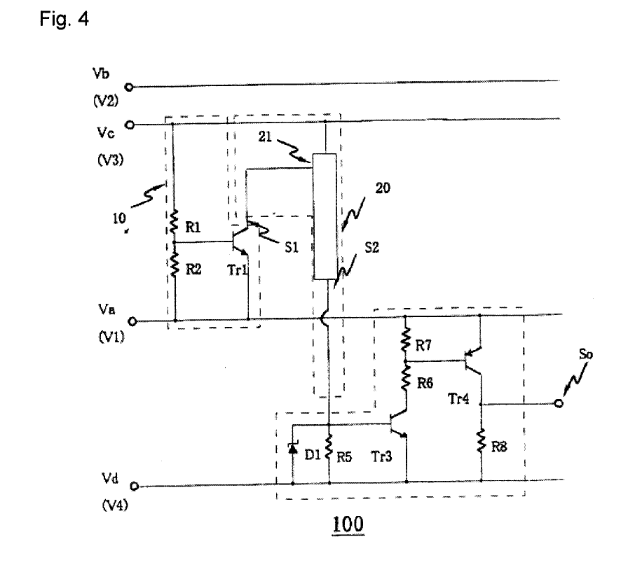

FIG. 4 is a diagram showing another preferred embodiment of the semiconductor device 100 of the present invention. The same numbers are used for constituent elements that are the same as those shown in FIG. 2, and a detailed description thereof is omitted. Because the only element that is different from FIG. 2 is the auxiliary circuit 20, a description of the detection circuit 10 and signal output circuit 30 is omitted.

The auxiliary circuit 20 includes a level shifter 21, one end of which is connected to the output of the detection circuit 10 (i.e., the collector terminal of the first transistor Tr1), and which outputs the second output signal S2 as an output of the auxiliary circuit 20. The level shifter 21 uses the third voltage V3 and fourth voltage V4 as the power supply voltage.

The operation of the auxiliary circuit 20 will be described below. The first output signal S1 is input into the level shifter 21 from the detection circuit 10. For instance, a voltage corresponding to the third voltage V3 is input, and a voltage corresponding thereto between the fourth voltage V4 and first voltage V1 is output from the level shifter 21. Accordingly, the second output signal S2 is output to the signal output circuit 30.

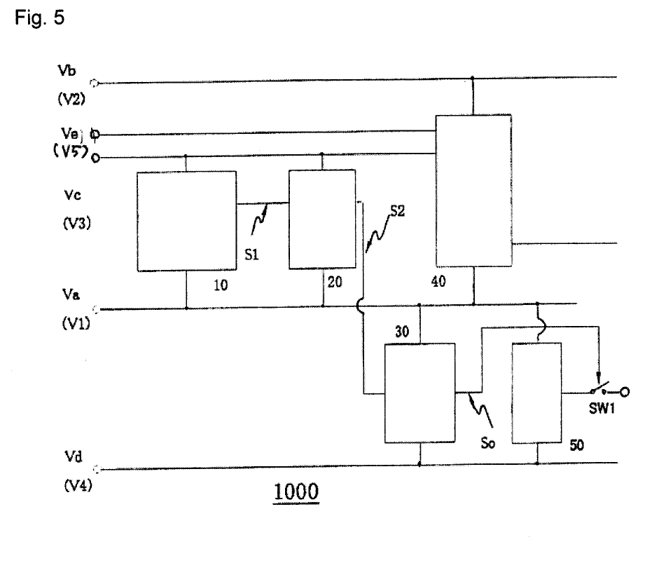

FIG. 5 is a diagram showing an electrical device 1000 using the semiconductor device 100 of the present preferred embodiment. For constituent elements that are the same as those shown in FIGS. 1 through 4, the same numbers are used, and a detailed description thereof is omitted. The electrical device 1000 of the present preferred embodiment includes one of the semiconductor devices 100 described in FIGS. 1 through 4 (detection circuit 10, auxiliary circuit 20, and signal output circuit 30), a logic circuit 40, a negative output constant voltage source 50 which outputs a negative voltage on the basis of the fourth voltage V4 and first voltage V1, and a first switch SW1 which is switched on or off depending on whether or not the negative voltage that is output from the negative output constant voltage source 50 is supplied to an external device of the semiconductor device 100 by the third output signal So from the semiconductor device 100. Furthermore, as is shown in the figure, besides a fifth voltage V5 (V1<V5<V2) applied to a fifth terminal Ve, the third voltage V3 from the third terminal Vc that is also used as the power supply voltage of the semiconductor device 100 of the present preferred embodiment may also be input into the logic circuit 40. For example, it is preferable to use a chip enable signal which is a signal that makes a transition to a high level (third voltage V3) from the start of the electrical device 1000 and that does not change thereafter, or a start signal as a signal that is input into the third terminal Vc. Moreover, even in the case of a signal that changes from the start time, e.g., in a case where the signal applied to the third terminal Vc changes from 1.5 V to 2.5 V with the first reference voltage Vref1 and second reference voltage Vref2 being 1.1 V, the lower limit of this fluctuation does not reach the first reference voltage Vref1 or lower, so that such a signal can also be used in a similar manner.

As was described above, because the present preferred embodiment can operate without depending on the second voltage V2, the input order of the negative-side circuit (i.e., the signal output circuit 30 and negative output constant voltage source 50 in FIG. 5) can be set without considering the order of the application of the power supplies. Therefore, the designing of electrical devices using the present preferred embodiment is facilitated.

Furthermore, because a negative voltage can be used as the fourth voltage V4 applied to the fourth terminal Vd, the fourth voltage V4 can be controlled without increasing the third voltage V3. Accordingly, the operating voltage used in the switching-side logic circuit 40 can also be lowered. It is no longer required to use a high withstanding voltage element that would be used in order to make the logic circuit 40 withstand the operation of a high voltage. Because the area of a high withstand voltage element is larger than that of an ordinary element, a reduction in the circuit area also becomes possible. Moreover, because there is no need to use a high voltage as a positive power supply voltage, a reduction in power consumption also becomes possible.

### Fifth Preferred Embodiment

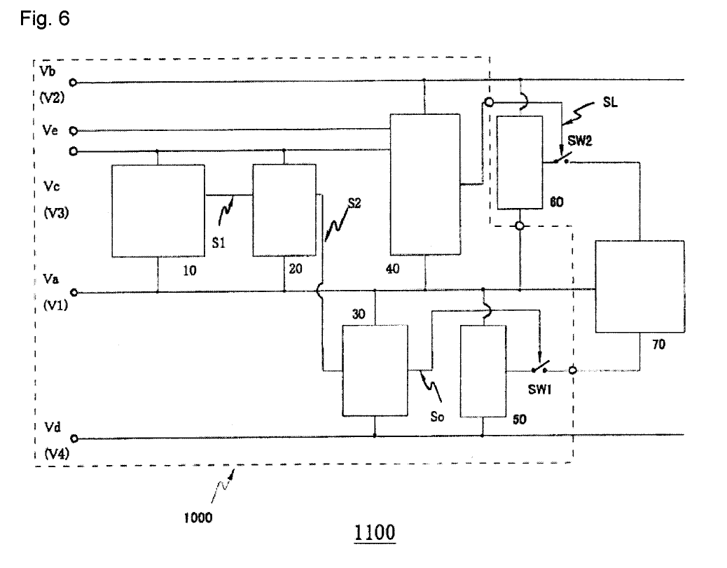

FIG. 6 is a diagram showing an image pickup device 1100, e.g., a digital still camera or digital video camera, using the electrical device 1000. For constituent elements that are the same as those shown in FIGS. 1 through 5, the same numbers are used, and a detailed description thereof is omitted. The image pickup device 1100 of the present preferred embodiment includes the electrical device 1000 described in FIG. 5 (utilizing one of the semiconductor devices described in FIGS. 1 through 4), a positive output constant voltage source 60 which outputs a positive voltage on the basis of the first voltage V1 and second voltage V2, a second switch SW2 which is switched on or off depending on whether or not the positive voltage that is output from the positive output constant voltage source 60 is supplied to an external device of the semiconductor device 100 by a logic signal SL from the logic circuit 40, and a CCD (charge-coupled device) image sensor 70. The positive output constant voltage source 60 and second switch SW2 are described as externally attached to the electrical device 1000; however, it would also be possible to install these elements in the interior of the electrical device 1000, or to form a semiconductor device in which these elements are provided on a single semiconductor substrate. The CCD image sensor 70 includes photoelectric conversion elements that convert optical signals that are input into respective pixels into electrical signals, and a charge-transfer portion that transfers the charge accumulated in the respective photoelectric conversion elements.

Three voltages, i.e., the second voltage V2 (positive voltage) used for photoelectric conversion element read-out, and the first voltage V1 (ground voltage) and fourth voltage V4 (negative voltage) for charge transfer, are used in the CCD image sensor 70. Accordingly, the operation is possible without depending on a positive power supply voltage by using a semiconductor device that has two or more power supply voltages as in the present application. Thus, there is no restriction on the order of the application of power supplies, which eliminates the need for a program or circuit that sets the input order of the negative-side circuit, so that the designing of an image pickup device of the present preferred embodiment is facilitated.

Furthermore, as was described above, the maximum voltage among the power supply voltages can be lowered, so that it is possible to reduce the power consumption. Consequently, the present preferred embodiment may also be used in an electrical device that utilizes a battery in a portable device as the power supply voltage.

The description above preferably involves the use of bipolar transistors as the transistors; however, these may be replaced by MOS transistors as appropriate. In addition, NPN transistors and PNP transistors may also be appropriately replaced according to the usage.

### Sixth Preferred Embodiment

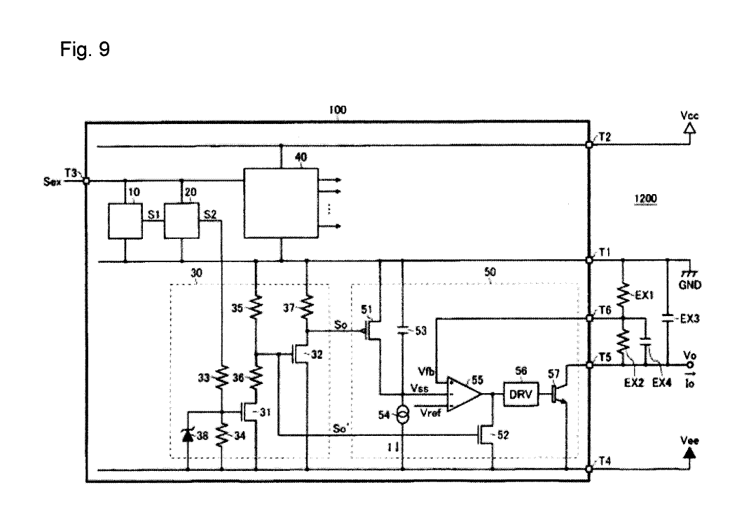

FIG. 9 is a circuit diagram showing a power supply device using the semiconductor device according to the preferred embodiments of the present invention.

As is shown in this figure, the power supply device 1200 of the present preferred embodiment includes the semiconductor device 100, and as elements externally attached thereto, an external resistor EX1 (resistance value: r1) and an external resistor EX2 (resistance value: r2) that define a resistive divider circuit, an external capacitor EX3 (capacitance value: Co) defining an output smoother, and an external capacitor EX4 (capacitance value: Css (several tens nF)) defining an external soft-start circuit.

The semiconductor device 100 includes a detection circuit 10, an auxiliary circuit 20, a signal output circuit 30, a logic circuit 40, and a negative voltage output regulator (negative constant voltage source) 50.

The detection circuit 10 uses, not a positive power supply voltage Vcc applied to a positive power supply terminal T2, but rather an external signal Sex that is input into an external signal terminal T3 and a ground voltage GND applied to a ground terminal T1 as the operating voltage. When the voltage level of the external signal Sex reaches a specified value, for example, when a chip enable signal or start signal that is input as the external signal Sex makes a transition to a high level (enable logic), the first output signal S1 is output. The specific arrangement and operation of the detection circuit 10 are as described previously, so that a detailed description thereof is omitted here.

As in the case of the detection circuit 10, the auxiliary circuit 20 also uses, not a positive power supply voltage Vcc applied to a positive power supply terminal T2, but uses an external signal Sex that is input into an external signal terminal T3 and a ground voltage GND applied to a ground terminal T1 as the operating voltage, and when the first output signal S1 is input, the second output signal S2 is output. The specific arrangement and operation of the auxiliary circuit 20 are also as described previously, so that a detailed description thereof is omitted here.

The signal output circuit 30 preferably includes N channel-type field-effect transistors 31 and 32, resistors 33 through 37, and a Zener diode 38.

One end of the resistor 33 is connected to the output end of the auxiliary circuit 20. The other end of the resistor 33 is connected to the gate of the transistor 31, one end of the resistor 34, and the cathode of the Zener diode 38. The source of the transistor 31, the other end of the resistor 34, and the anode of the Zener diode 38 are all connected to the negative power supply terminal T4 to which a negative power supply voltage Vee is applied. The drain of the transistor 31 is connected to one end of the resistor 36. The other end of the resistor 36 is connected to the gate of the transistor 32 and one end of the resistor 35. The source of the transistor 32 is connected to the negative power supply terminal T4. The drain of the transistor 32 is connected to one end of the resistor 37. The respective other ends of the resistor 35 and resistor 37 are both connected to the ground terminal T1.

The operation of the signal output circuit 30 will be described in detail below along with the operation of the negative voltage output regulator 50.

The logic circuit 40 uses a positive power supply voltage Vcc applied to the positive power supply terminal T2 and a ground voltage GND applied to the ground terminal T1 as the operating voltage, and controls various operations (yes/no control of the output of the positive constant voltage source 60 described in FIG. 6) based on the external signal Sex or the like that is input into the external signal terminal T3.

The negative voltage output regulator 50 includes a P-channel-type field-effect transistor 51, an N-channel-type field-effect transistor 52, a capacitor 53 (capacitance value: Cs (e.g., 100 pF)) used as a built-in soft-start circuit, a constant current source 54 (constant current value: I), an amplifier 55, a driver 56, and an npn-type bipolar transistor 57 (output power transistor).

The source of the transistor 51 and one end of the capacitor 53 are both connected to the ground terminal T1. The drain of the transistor 51 and the other end of the capacitor are both connected to one end of the constant current source 54 and a first inverting input end (−) of the amplifier 55. The gate of the transistor 51 is connected to the drain of the transistor 32. The other end of the constant current source 54 is connected to the negative power supply terminal T4. A second inverting input end (−) of the amplifier 55 is connected to the application end of a reference voltage Vref. The non-inverting input end (+) of the amplifier 55 is connected to a feedback terminal T6 to which a feedback voltage Vfb is applied. The output end of the amplifier 55 is connected to the input end of the driver 56 and the drain of the transistor 52. The source of the transistor 52 is connected to the negative power supply terminal T4. The gate of the transistor 52 is connected to the gate of the transistor 32. The output end of the driver 56 is connected to the base of the transistor 57. The collector of the transistor 57 is connected to the output terminal T5 from which an output voltage V0 is led out. The emitter of the transistor 57 is connected to the negative power supply terminal T4.

On the outside of the semiconductor device 100, the external capacitor EX3 is connected between the output terminal T5 and ground terminal T1 as the output smoother. Furthermore, the external resistors EX1 and EX2 are connected in series between the output terminal T5 and ground terminal T1 to generate the feedback voltage Vfb corresponding to the output voltage V0. The connection node of the external resistors EX1 and EX2 is connected to the feedback terminal T6 as the lead-out end of the feedback voltage Vfb. The external capacitor EX4 (speed-up capacitor) is connected between the output terminal T5 and feedback terminal T6 as the external soft-start circuit.

Next, the starting operation of the power supply device 1200 of the above-mentioned arrangement will be described in detail.

When the first output signal S1 is generated by the detection circuit 10 in response to the input of the external signal Sex, the second output signal S2 is supplied to the signal output circuit 30 from the auxiliary circuit 20. As a result, the gate voltage of the transistor 31 that is led out from the connection node of the resistors 33 and 34 shifts from a low level to a high level, and the transistor 31 makes a transition from off to on.

Furthermore, in cases where an unintended high voltage is applied to the external signal terminal T3, the Zener diode 38 functions as a clamp for preventing the gate voltage of the transistor 31 from abnormally rising as a result of following the potential of the external signal terminal T3. Moreover, the resistor 33 functions as a current limiter for limiting a current that flows when the Zener diode 38 is switched on.

When the transistor 31 is switched on, the gate voltage (start signal So′ of the negative voltage output operation) of the transistor 52 that is led out from the connection node of the resistors 35 and 36 shifts from a high level to a low level, and the transistor 52 makes a transition from on to off. As a result, the output signal of the amplifier 55 is applied to the driver 56 without being reduced to the negative power supply voltage Vee, so that the negative voltage output operation (generation operation of the output voltage V0) is initiated.

When the transistor 31 is switched on, the gate voltage of the transistor 32 that is led out from the connection node of the resistor 35 and 36 shifts from a high level to a low level, and the transistor 32 makes a transition from on to off. As a result, the gate voltage (start signal So of the soft-start operation) of the transistor 51 that is led out from the drain of the transistor 32 shifts from a low level to a high level, so that the transistor 51 makes a transition from on to off. Accordingly, the bypass path of the capacitor 53 via the transistor 51 is cut off, so that the charging of the capacitor 53 by a constant current I is initiated, thus initiating the soft-start operation (generation operation of the soft-start voltage Vss). The soft-start voltage Vss that is generated at this point defines a voltage signal that gradually makes a transition to a lower potential as the charging of the capacitor 53 progresses after the transistor 51 is switched off.

In the negative voltage output regulator 50, the opening-and-closing control of the transistor 57 is performed so that the higher potential of either the reference voltage Vref or soft-start voltage Vss coincides with the feedback voltage Vfb corresponding to the output voltage V0 at the time of the negative voltage output operation. Therefore, a desired output voltage V0 is generated from the negative power supply voltage Vee.

Thus, in the power supply device 1200 of the present preferred embodiment, because the negative voltage output regulator 50 can be caused to operate without depending on the positive power supply voltage Vcc, there is no need to worry about the order of the application of the power supplies, which makes it possible to facilitate the designing of electrical devices using the power supply device 1200.

The image pickup device shown in FIG. 6 or the like can be cited as an example of the application of the power supply device 1200 of the present preferred embodiment. Specifically, an image pickup device including the power supply device 1200 of the present preferred embodiment and a CCD image sensor 70 is conceivable, with this device having an arrangement that uses a positive power supply voltage Vcc (or a positive voltage generated from this), a negative output voltage V0 that is generated by the negative voltage output regulator 50, and a ground voltage GND as the operating voltage of the CCD image sensor 70.

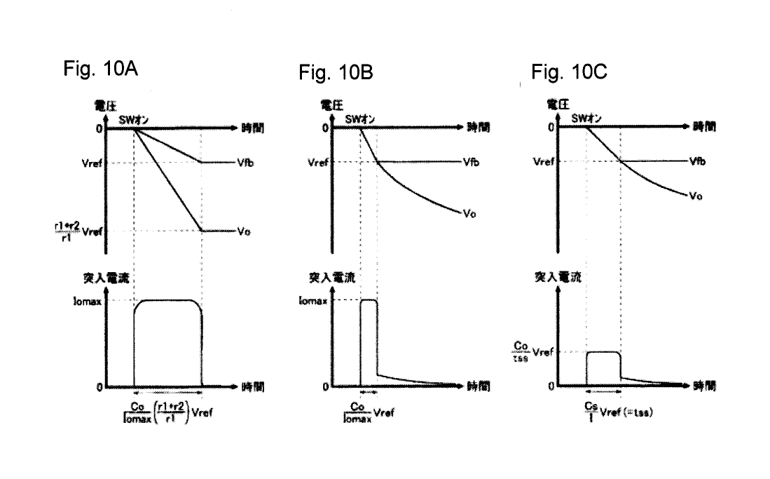

Finally, the effect of the soft-start function of the present preferred embodiment will be described in detail with reference to FIGS. 10A-10C.

FIGS. 10A to 10C are diagrams used to illustrate the effect of the soft-start function of the preferred embodiments of the present invention. The respective upper portions in FIGS. 10A through 10C show a transition of the output voltage V0 and feedback voltage Vfb immediately following the start. The respective lower portions in FIGS. 10A through 10C show a transition of the incoming current immediately following the start.

First, with reference to FIG. 10A, a case in which absolutely no soft-start function is provided (i.e., a case in which none of the transistor 51, capacitor 53, constant current source 54, and external capacitor EX4 is provided in the arrangement shown in FIG. 9) will be described just for reference.

In cases where no soft-start function is provided at all, the negative voltage output regulator 50 causes the maximum output current Io capability to flow until the output voltage V0 reaches the target value ((r1+r2)/r1×Vref), and charges the output smoothing external capacitor EX3. Accordingly, the maximum value of the incoming current flowing in this case is an excessively large current that reaches the maximum value Iomax of the output current Io, and this excessively large current continuously flows over a long period of time which is (Co/Iomax)×((r1+r2)/r1×Vref).

Next, a case of introducing only the external capacitor EX4 defining the externally attached soft-start function (speed-up function) will be described with reference to FIG. 10B.

Because the external capacitor EX4 is not charged immediately following the start, the external resistor EX2 is shorted by the external capacitor EX4, so that a state is created in which the output voltage V0 is fed back and input “as is” as the feedback voltage Vfb (total feedback state). That is, the negative voltage output regulator 50 is in a buffer state. As a result, the amplifier 55 (hence, the transistor 57) is fully switched on, and the output voltage V0 is raised up at one time to the reference voltage Vref.

Accordingly, the voltage used to charge the external capacitor EX3 is reduced to Vref from the above-mentioned value ((r1+r2)/r1×Vref) as a result of the introduction of the external capacitor EX4, so that the time during which the incoming current flows can be shortened to ((Co/Iomax)×Vref). In other words, the external capacitor EX4 is provided as a result of noticing that it is possible to reduce the period of time for the negative voltage output regulator 50 to flow the maximum current capability by increasing the stability of the output voltage V0.

Subsequently, when the output voltage V0 reaches the reference voltage Vref, the feedback voltage Vfb settles at the same value as the reference voltage Vref. However, the output voltage V0 is continuously charged up by causing a current to flow through the external resistor EX2 and external capacitor EX4 until this output voltage V0 reaches the target value ((r1+r2)/r1×Vref). Upon reaching this target value, the output voltage V0 is finally stabilized.

Next, a case of introducing a built-in soft-start circuit (transistor 51, capacitor 53, and constant current source 54) in addition to the external capacitor EX4 will be described with reference to FIG. 10C.

The soft-start for the output operation of the amplifier 55 is applied using the soft-start voltage Vss generated by the constant current source 54 and capacitor 53 inside the semiconductor device 100 with respect to the incoming current flow time that has been shortened by the introduction of the external capacitor EX4. As a result, the incoming current flow time tss is increased to (Cs/I)×Vref; however, the maximum value of the incoming current can be reduced to a value lower than Iomax, i.e., ((Co/tss)×Vref).

Because the above-mentioned external capacitor EX4 is provided in parallel to the external resistor EX2, it is not necessary to additionally provide an external terminal dedicated to connect a capacitor. Moreover, as is shown in FIG. 10C, because the incoming current flow time is shortened, there is no need to increase the capacitance value of the capacitor 53 unnecessarily or to reduce the current value of the constant current source 54 to an extreme extent. Accordingly, the power supply device 1200 of the present preferred embodiment makes it possible to effectively minimize the incoming current generated at the start of the device while also minimizing an increase in the package size or chip area.

In addition, in the above-mentioned preferred embodiment, a description is given by citing an example of a soft-start operation achieved by controlling the opening and closing of the transistor 57 so that the higher potential of either a specified reference voltage Vref or soft-start voltage Vss coincides with a feedback voltage Vfb corresponding to the output voltage V0 (i.e., an arrangement in which the soft-start is applied to the reference voltage Vref). However, the present invention is not limited to this; as another example, it would also be possible to use an arrangement in which the soft-start operation is achieved by giving an offset to the input voltage level of the driver 56 (i.e., the output voltage level of the amplifier 55) in accordance with the soft-start voltage Vss (i.e., an arrangement in which the soft-start is applied to the control signal itself of the transistor 57).

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A semiconductor device comprising:
an internal circuit having a positive power supply voltage and a negative power supply voltage;
an external input controlling the operation of the internal circuit;
an input signal detection circuit arranged to receive a voltage as the external input; and
a signal output circuit arranged to output a signal to control the negative power supply voltage applied to the internal circuit in accordance with an output of the input signal detection circuit.

2. A semiconductor device comprising:
a first terminal to which a first voltage is applied;
a second terminal to which a second voltage that is higher than the first voltage is applied;
a third terminal to which a third voltage that is between the first voltage and the second voltage is applied;
a fourth terminal to which a fourth voltage that is lower than the first voltage is applied;
a detection circuit into which an input signal from the third terminal and a specified first reference voltage between the first voltage and second voltage are input, and which outputs a first output signal in accordance with the difference between the input signal and the first reference voltage;
an auxiliary circuit into which the first output signal of the detection circuit and a specified second reference voltage between the first voltage and the second voltage are input; and
a signal output circuit into which a third reference voltage that is a specified voltage between the first voltage and the fourth voltage and a second output signal from the auxiliary circuit are input, and which outputs a third output signal in accordance with the second output signal; wherein
the third output signal is output in accordance with the signal that is input into the third terminal.

3. The semiconductor device according to claim 2, wherein the first reference voltage is output from a connection point between a first resistor, one end of which is connected to the first terminal, and a second resistor, one end of which is connected to the third terminal and the other end of which is connected to the other end of the first resistor.

4. The semiconductor device according to claim 3, wherein the detection circuit includes a first transistor having a base terminal connected to the connection point between the first resistor and the second resistor, and an emitter terminal connected to the first terminal, wherein the first output signal is an output signal from a collector terminal of the first transistor.

5. The semiconductor device according to claim 2, wherein the second reference voltage is output from a connection point between a third resistor one end of which is connected to the first output signal of the detection circuit and a fourth resistor, one end of which is connected to the other end of the third resistor and the other end of which is connected to the third terminal.

6. The semiconductor device according to claim 5, wherein the auxiliary circuit includes a second transistor having a base terminal connected to the connection point between the third resistor and the fourth resistor, and an emitter terminal connected to the third terminal, wherein the second output signal is a voltage generated at the fourth resistor that is connected between a collector terminal of the second transistor and the third terminal.

7. A semiconductor device comprising:
a first terminal to which a first voltage is applied;
a second terminal to which a second voltage that is higher than the first voltage is applied;
a third terminal to which a third voltage that is between the first voltage and the second voltage is applied;
a fourth terminal to which a fourth voltage that is lower than the first voltage is applied;
a detection circuit into which an input signal from the third terminal and a specified first reference voltage between the first voltage and second voltage are input, and which outputs a first output signal in accordance with the difference between the input signal and the first reference voltage;
an auxiliary circuit which outputs a second output signal in accordance with a signal input into the third terminal by an input-side transistor of a current mirror having an emitter connected to the third terminal, and into which the first output signal is input, and an output-side transistor of the current mirror; and
a signal output circuit into which a third reference voltage that is a specified voltage between the first voltage and the fourth voltage and the second output signal from the auxiliary circuit are input, and which outputs a third output signal in accordance with the second output signal; wherein
the third output signal is output in accordance with the signal that is input into the third terminal.

8. A semiconductor device comprising:
a first terminal to which a first voltage is applied;
a second terminal to which a second voltage that is higher than the first voltage is applied;
a third terminal to which a third voltage that is between the first voltage and the second voltage is applied;
a fourth terminal to which a fourth voltage that is lower than the first voltage is applied;
an auxiliary circuit having a level shift circuit which is connected to the third terminal, and into which a first output signal is input; and
a signal output circuit into which a third reference voltage that is a specified voltage between the first voltage and the fourth voltage and a second output signal from the auxiliary circuit are input, and which outputs a third output signal in accordance with the second output signal; wherein
the third output signal is output in accordance with a signal that is input into the third terminal.

9. The semiconductor device according to claim 2, wherein the signal output circuit includes the first terminal, an input portion into which the second output signal from the auxiliary circuit is input, and a clamp circuit arranged to prevent a voltage that is equal to or higher than a specified fifth voltage from being applied to the input portion.

10. An image pickup device using a CCD image sensor that uses the first voltage, the second voltage, and the third voltage as an operating voltage, and including the semiconductor device according to claim 2.

11. A semiconductor device comprising:
a positive power supply terminal arranged to receive a supply of a positive power supply voltage;
a negative power supply terminal arranged to receive a supply of a negative power supply voltage;
a ground terminal arranged to receive a supply of a ground voltage;
an external signal terminal arranged to receive an external signal input that can gain a positive voltage level;
a negative voltage output regulator arranged to use the negative power supply voltage and the ground voltage as an operating voltage and to initiate an output operation of a negative voltage in accordance with a specified start signal;
a detection circuit arranged to use the external signal and the ground voltage as the operating voltage and to generate a specified output signal when the voltage level of the external signal reaches a specified value; and
a signal output circuit arranged to use the negative power supply voltage and the ground voltage as the operating voltage and to generate the start signal in accordance with the output signal.

12. The semiconductor device according to claim 11, further comprising an output terminal arranged to output an output voltage of the negative voltage output regulator, and a feedback terminal that receives a feedback voltage input corresponding to the output voltage, and the negative voltage output regulator includes a power transistor connected between the output terminal and the negative power supply terminal and a driver arranged to control the opening and closing of the power transistor so that the feedback voltage and a specified reference voltage coincide.

13. A power supply device comprising:
the semiconductor device according to claim 12;
an output smoothing capacitor externally connected between the output terminal and the ground terminal; and
first and second external resistors externally connected in series between the output terminal and the ground terminal, and having a connection node externally connected to the feedback terminal.

14. The power supply device according to claim 13, further comprising a speed-up capacitor externally connected between the output terminal and the feedback terminal.

15. The power supply device according to claim 14, wherein the negative voltage output regulator includes a soft-start circuit arranged to generate a voltage signal that initiates a gradual transition of the voltage level using the start signal as a trigger, and which applies a soft-start to the reference voltage or the control signal of the power transistor using the voltage signal.

16. An image pickup device comprising:
the power supply device according to claim 13; and
a CCD image sensor; wherein
the positive power supply voltage or a positive voltage produced from the positive power supply voltage, a negative voltage produced by the negative voltage output regulator, and the ground voltage are used as an operating voltage of the CCD image sensor.

17. The semiconductor device according to claim 7, wherein the signal output circuit includes the first terminal, an input portion into which the second output signal from the auxiliary circuit is input, and a clamp circuit arranged to prevent a voltage that is equal to or higher than a specified fifth voltage from being applied to the input portion.

18. An image pickup device using a CCD image sensor that uses the first voltage, the second voltage, and the third voltage as an operating voltage, and including the semiconductor device according to claim 7.

19. The semiconductor device according to claim 8, wherein the signal output circuit includes the first terminal, an input portion into which the second output signal from the auxiliary circuit is input, and a clamp circuit arranged to prevent a voltage that is equal to or higher than a specified fifth voltage from being applied to the input portion.

20. An image pickup device using a CCD image sensor that uses the first voltage, the second voltage, and the third voltage as an operating voltage, and including the semiconductor device according to claim 8.
